(19) United States
(12) Patent Application Publication
(10) Pub. No.: US 2026/0239742 A1
(43) Pub. Date: Aug. 13, 2026

(54) DRIVING BACKPLANE, DISPLAY PANEL, AND TILED DISPLAY DEVICE

(71) Applicants: BOE MLED Technology Co., Ltd., Beijing (CN); BOE Technology Group Co., Ltd., Beijing (CN)

(72) Inventors: Sen YAN, Beijing (CN); Yicheng LIN, Beijing (CN); Qingkai ZHANG, Beijing (CN); Qiuhua MENG, Beijing (CN); Huanxin YUE, Beijing (CN); Linfeng LI, Beijing (CN); Zeng LIANG, Beijing (CN)

(21) Appl. No.: 19/152,026

(22) PCT Filed: Jun. 13, 2024
(86) PCT No.: PCT/CN2024/099044

§ 371 Date: Jul. 30, 2025

(30) Foreign Application Priority Data
Jul. 21, 2023 (CN) 202310907539.4

(51) Int. Cl. H10D 86/40; H10H 29/49

(52) U.S. Cl. CPC H10D 86/441; H10H 29/49

(57) ABSTRACT

A driving backplane, a display panel, and a tiled display device are disclosed. The driving backplane includes: a base substrate; a pixel driving circuit located on the base substrate; and a wiring layer on a side of the pixel driving circuit away from the base substrate, wherein the wiring layer comprises a pattern of a potential wire and a pattern of a bonding electrode, and the bonding electrode is used for bonding a micro light emitting diode; where a distance between an outermost edge of the wiring layer and an edge of the base substrate on the same side as the outermost edge of the wiring layer is smaller than a distance between an outermost edge of the pixel driving circuit and an edge of the base substrate on the same side as the outermost edge of the pixel driving circuit.

### CROSS-REFERENCE TO RELATED APPLICATIONS

This application is a National Stage of International Application No. PCT/CN2024/099044, filed on Jun. 13, 2024, which claims priority to Chinese Patent Application No. 202310907539.4, filed with the China National Intellectual Property Administration on Jul. 21, 2023, and entitled “Driving Backplane, Display Panel, and Tiled Display Device”, the content of which is hereby incorporated by reference in its entirety.

### TECHNICAL FIELD

The present disclosure relates to the technical field of display, and in particular to a driving backplane, a display panel, and a tiled display device.

### BACKGROUND

Mini Light Emitting Diode (Mini LED) or Micro Light Emitting Diode (Micro LED) is a miniaturized LED array structure, has advantages of ultra-high contrast, wide color gamut, low power consumption, can be tiled and so on, and is widely used.

For production, the yield is the main factor affecting the cost. However, the high incidence of Electro-Static Discharge (ESD) in the production process directly leads to the reduction of product yield, resulting in an increase in cost.

### SUMMARY

The present disclosure provides a driving backplane, a display panel, and a tiled display device. Specific schemes are as follows.

Embodiments of the present disclosure provide a driving backplane, including:
a base substrate;
a pixel driving circuit on the base substrate; and
a wiring layer on a side of the pixel driving circuit away from the base substrate, where the wiring layer includes a pattern of a potential wire and a pattern of a bonding electrode, and the bonding electrode is used for bonding a micro light emitting diode;
where a distance between an outermost edge of the wiring layer and an edge of the base substrate on the same side as the outermost edge of the wiring layer is smaller than a distance between an outermost edge of the pixel driving circuit and an edge of the base substrate on the same side as the outermost edge of the pixel driving circuit.

Optionally, in embodiments of the present disclosure, the driving backplane further includes a transfer electrode located between the potential wire and the base substrate, and electrically connected with the potential wire and the pixel driving circuit respectively, where an orthographic projection of the potential wire on the base substrate and an orthographic projection of the transfer electrode on the base substrate are in a mesh structure, and the mesh structure is configured as an electrostatic protection unit.

Optionally, in embodiments of the present disclosure, the potential wire includes an edge wire at an outermost side and a middle wire in a middle region, where a line width of the edge wire is smaller than a line width of the middle wire.

Optionally, in embodiments of the present disclosure, the bonding electrode at the outermost edge of the wiring layer is flush with the edge wire on the same side as the bonding electrode.

Optionally, in embodiments of the present disclosure, the base substrate is divided into a plurality of lamp regions arranged in an array; where adjacent two lamp regions in the plurality of lamp regions are arranged equidistantly, and each of the lamp regions is configured to be electrically connected with a corresponding micro light emitting diode through the potential wire and the bonding electrode of a corresponding region.

Optionally, in embodiments of the present disclosure, along a direction away from the base substrate, a conductive layer of the pixel driving circuit includes a first gate layer, an active layer, a second gate layer and a first source-drain electrode layer sequentially arranged; the driving backplane includes an insulating layer and a second source-drain electrode layer sequentially arranged on a side of the first source-drain electrode layer away from the base substrate; the transfer electrode is in the first source-drain electrode layer, and the potential wire and the bonding electrode are in the second source-drain electrode layer.

Optionally, in embodiments of the present disclosure, along an extending direction of the outermost edge of the wiring layer, an edge wire is arranged discontinuously to form a plurality of discontinuous parts, and the discontinuous parts are electrically connected through a transfer electrode formed from the first source-drain electrode layer.

Optionally, in embodiments of the present disclosure, an orthographic projection of the outermost edge of the pixel driving circuit on the base substrate is overlapped with an orthographic projection of an edge of the first source-drain electrode layer on the same side as the outermost edge of the pixel driving circuit on the base substrate.

Optionally, in embodiments of the present disclosure, the distance between the outermost edge of the wiring layer and the edge of the base substrate on the same side as the outermost edge of the wiring layer is in a range of 139 μm to 179 μm, and the distance between the outermost edge of the pixel driving circuit and the edge of the base substrate on the same side as the outermost edge of the pixel driving circuit is in a range of 180 μm to 220 μm.

Correspondingly, embodiments of the present disclosure provide a display panel, including: the above driving backplane, and a plurality of micro light emitting diodes bonded on the driving backplane.

Correspondingly, embodiments of the present disclosure provide a tiled display device, including: a plurality of display panels each according to the above display panel.

### BRIEF DESCRIPTION OF FIGURES

FIG. 1 is a schematic diagram of a top view structure of a driving backplane in related art;

FIG. 2 is a schematic diagram of a top view structure of a driving backplane according to an embodiment of the present disclosure;

FIG. 3 is a schematic diagram of a sectional structure along a direction indicated by MM in FIG. 2;

FIG. 4 is a schematic diagram of a sectional structure along a direction indicated by MM in FIG. 2;

FIG. 5 is a schematic diagram of a top view structure of arrangement of a potential wire and a transfer wire in a driving backplane according to an embodiment of the present disclosure;

FIG. 6 is a schematic diagram of a top view structure of a potential wire in a driving backplane according to an embodiment of the present disclosure;

FIG. 7 is a schematic diagram of a top view structure of a driving backplane according to an embodiment of the present disclosure;

FIG. 8 is a schematic view of a sectional structure along a direction indicated by MM in FIG. 2;

FIG. 9 is a schematic diagram of a top view structure of an edge wire in a driving backplane according to an embodiment of the present disclosure;

FIG. 10 is a pattern of a first gate layer in a region Q in FIG. 2;

FIG. 11 is a pattern of an active layer in a region Q in FIG. 2;

FIG. 12 is a pattern of a second gate layer in a region Q in FIG. 2;

FIG. 13 is a pattern of a first source-drain electrode layer in a region Q in FIG. 2;

FIG. 14 is a pattern of a second source-drain electrode layer in a region Q in FIG. 2;

FIG. 15 is a pattern after associated conductive layers in a region Q in FIG. 2 are superimposed;

FIG. 16 is a schematic structural diagram of a display panel according to an embodiment of the present disclosure;

FIG. 17 is a schematic structural diagram of a tiled display device according to an embodiment of the present disclosure;

FIG. 18 is a schematic diagram of a partial top view structure of two display panels tiled together;

FIG. 19 is a simplified top view structure before a part of a pixel driving circuit in a single display panel of FIG. 18 moves inward;

FIG. 20 is a simplified top view structure after a part of a pixel driving circuit in a single display panel of FIG. 18 moves inward.

### DETAILED DESCRIPTION

For making objectives, technical solutions and advantages of embodiments of the present disclosure clearer, technical solutions of embodiments of the present disclosure will be clearly and completely described below in combination with accompanying drawings in embodiments of the present disclosure. Apparently, embodiments described are some rather than all of embodiments of the present disclosure. Based on embodiments of the present disclosure, all other embodiments obtained by those of ordinary skill in the art without making creative efforts fall within the scope of protection of the present disclosure.

Unless otherwise defined, technical or scientific terms used in the present disclosure should have ordinary meanings as understood by those of ordinary skill in the art to which the present disclosure belongs. The words “first”, “second”, etc. used in the present disclosure do not indicate any order, quantity or importance, but are only used to distinguish different components. The word “including” or “comprising”, etc. indicates that elements or objects before the word include elements or objects after the word and their equivalents, without excluding other elements or objects. The word “connection” or “link”, etc. is not limited to physical or mechanical connections, but may include electrical connections, whether direct or indirect. “Inner”, “outer”, “upper”, “lower”, etc. are only used to indicate a relative positional relationship, and when an absolute position of a described object changes, the relative positional relationship may also change accordingly.

It should be noted that a size and a shape of each figure in the drawings do not reflect a true scale, but only for illustrating the present disclosure. Throughout the drawings, identical or similar reference numerals denote identical or similar elements or elements having identical or similar functions.

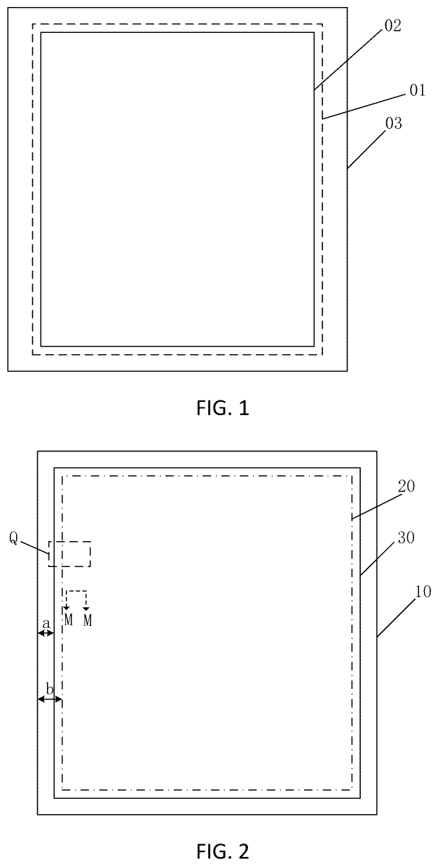

In the related art, a driving backplane as shown in FIG. 1 is often manufactured by a manufacturing process. 01 represents a region where a pixel circuit is disposed. 02 represents a region where a top conductive layer is disposed. 03 represents a backplane. The pixel circuit is closer to an edge of the driving backplane than the top conductive layer (e.g. Cu layer) to which the pixel circuit is coupled. In a production process of the driving backplane, the edge of the backplane is the most vulnerable position to ESD. When ESD occurs at the edge of the backplane during a manufacturing process, since the backplane is not connected with any signal, the pixel circuit is divided into a plurality of independent units by a plurality of corresponding thin-film transistors (Thin Film Transistor, TFT), a discharge path of the charge is blocked, and the ESD can cause damage to the pixel circuit, resulting in poor performance.

In view of this, embodiments of the present disclosure provide a driving backplane, a display panel and a tiled display device for effectively conducting away ESD, and improving yield of the backplane.

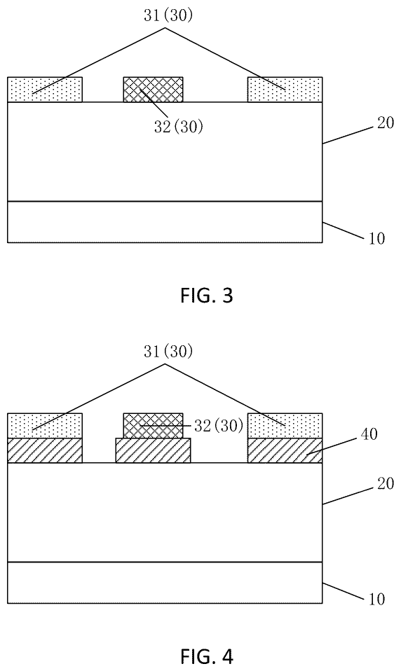

As shown in FIG. 2 and FIG. 3, FIG. 2 is a schematic diagram of a top view structure of a driving backplane provided according to an embodiment of the present disclosure. FIG. 3 is a schematic diagram of a sectional structure along a direction indicated by MM in FIG. 2.

The driving backplane includes:
a base substrate 10;

a pixel driving circuit 20 on the base substrate 10; and
a wiring layer 30 on a side of the pixel driving circuit 20 away from the base substrate 10. The wiring layer 30 includes a pattern of a potential wire 31 and a pattern of a bonding electrode 32, and the bonding electrode 32 is used for bonding a micro light emitting diode.

A distance between an outermost edge of the wiring layer 30 and an edge of the base substrate 10 on the same side as the outermost edge of the wiring layer 30 is smaller than a distance between an outermost edge of the pixel driving circuit 20 and an edge of the base substrate 10 on the same side as the outermost edge of the pixel driving circuit 20.

In a specific implementation process, the driving backplane includes a base substrate 10, a pixel driving circuit 20, and a wiring layer 30. Illustratively, the base substrate 10 may be a rigid substrate such as a glass substrate, a silicon-based substrate, or the like. The base substrate 10 may also be a flexible substrate, such as a Polyimide (PI) substrate. Of course, a specific material of the base substrate 10 may also be set according to actual application requirements, which is not limited herein. Moreover, the pixel driving circuit 20 is arranged on the base substrate 10, and the wiring layer 30 is located at a side of the pixel driving circuit 20 away from the base substrate 10. The wiring layer 30 includes a pattern of a potential wire 31 and a pattern of a bonding electrode 32. For example, the potential wire 31 and the bonding electrode 32 are made of conductive layers of the same layer and the same material. For example, the potential wire 31 may be a power wire with a constant potential, such as a high potential wire, a low potential wire, or the like. In practice, the bonding electrode 32 is used for bonding the micro light emitting diode. Accordingly, the pixel driving circuit 20 is used for driving the micro-light emitting diode to emit light and display. For example, the micro light emitting diode may be a Mini LED or a Micro LED, which is not limited herein. In practical application, the specific number and the arrangement mode of micro light emitting diodes can be set according to actual requirements, which are not limit herein.

In addition, the distance between the outermost edge of the wiring layer 30 and the edge of the base substrate 10 on the same side as the outermost edge of the wiring layer 30 is smaller than distance between the outermost edge of the pixel driving circuit 20 and the edge of the base substrate 10 on the same side as the outermost edge of the pixel driving circuit 20. Referring to FIG. 2, a represents the distance between the outermost edge of the wiring layer 30 and the edge of the base substrate 10 on the same side as the outermost edge of the wiring layer 30, and b represents the distance between the outermost edge of the pixel driving circuit 20 and the edge of the base substrate 10 on the same side as the outermost edge of the pixel driving circuit 20, and a<b. In this way, during the production process, even if ESD is generated at the outermost edge of the driving backplane, the ESD can be conducted preferentially through the wiring layer 30, avoiding accumulation of ESD at the pixel driving circuit 20, and improving the production yield of the driving backplane.

In embodiments of the present disclosure, the driving backplane further includes a transfer electrode 40 located between the potential wire 31 and the base substrate 10, and electrically connected with the potential wire 31 and the pixel driving circuit 20 respectively. An orthographic projection of the potential wire 31 on the base substrate 10 and an orthographic projection of the transfer electrode 40 on the base substrate 10 are in a mesh structure, and the mesh structure is configured as an electrostatic protection unit.

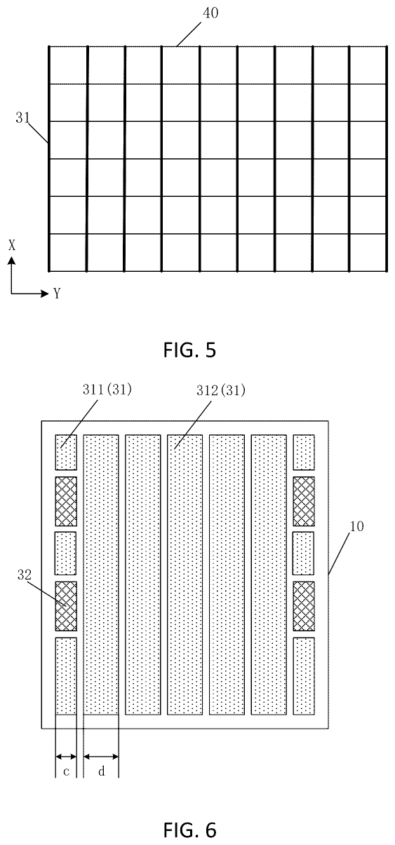

In a specific implementation process, FIG. 4 is a schematic diagram of a sectional structure along a direction indicated by MM in FIG. 2. The driving backplane further includes a transfer electrode 40 between the potential wire 31 and the base substrate 10, and electrically connected with the potential wire 31 and the pixel driving circuit 20 respectively. In this way, the potential wire 31 is effectively electrically connected with the pixel driving circuit 20 through the transfer electrode 40, driving control for the micro light emitting diode by the pixel driving circuit 20 is ensured. Moreover, the orthographic projection of the potential wire 31 on the base substrate 10 and the orthographic projection of the transfer electrode 40 on the base substrate 10 are arranged in a mesh structure. Accordingly, the mesh structure is configured as an electrostatic protection unit by which static electricity can be efficiently discharged. In this way, the same signal can be connected to form a corresponding mesh structure; the mesh structure has a low resistance, and is easier to conduct away static electricity, improving the electrostatic protection capability of the driving backplane. Taking an embodiment shown in FIG. 5 as an example, the potential wire 31 extends in a direction parallel to the outermost edge of the base substrate 10, as shown by an arrow X in FIG. 5. The transfer electrode 40 extends in a direction perpendicular to the outermost edge of the base substrate 10, as shown by an arrow Y in FIG. 5.

In an embodiment of the present disclosure, the potential wire 31 includes an edge wire 311 located at an outermost side and a middle wire 312 in a middle region. A line width of the edge wire 311 is smaller than a line width of the middle wire 312.

In a specific implementation process, as shown in FIG. 6, FIG. 6 is a schematic diagram of a top view structure of the potential wire 31. The potential wire 31 includes an edge wire 311 located at an outermost edge and a middle wire 312 located in a middle region. A line width of the edge wire 311 is smaller than a line width of the middle wire 312. In this way, on the premise of the same arrangement of micro light emitting diodes, the edge wire 311 occupies less edge space, and provides the possibility for subsequent seamless tiling. Still referring to an embodiment shown in FIG. 6, the line width of the edge wire 311 is c, the line width of the middle wire 312 is d, and c<d. It should be noted that, in practical applications, the maximum line width of the edge wire 311 may still be smaller than the line width of the middle wire 312.

In that embodiment of the present disclosure, the bonding electrode 32 located at the outermost edge of the wiring layer 30 is flush with the edge wire 311 on the same side as the bonding electrode 32.

In a specific implementation process, as shown in FIG. 6, the bonding electrode 32 located at the outermost edge of the wiring layer 30 is flush with the edge wire 311 on the same side as the bonding electrode 32. In this way, on the premise of the same arrangement of the micro light emitting diodes, the occupied space of the edge wiring 311 can be effectively reduced. Accordingly, the edge wire 311 occupies less edge space, providing a possibility for subsequent seamless tiling.

In embodiments of the present disclosure, the base substrate 10 is divided into a plurality of lamp regions 50 arranged in an array. Adjacent two lamp regions 50 in the plurality of lamp regions 50 are arranged equidistantly, and each of the lamp regions 50 is configured to be electrically connected with a corresponding micro light emitting diode through the potential wire 31 and the bonding electrode 32 of a corresponding region.

In a specific implementation process, as shown in FIG. 7, FIG. 7 is a schematic diagram of a top view structure of a driving backplane. The base substrate 10 is divided into a plurality of lamp regions 50 arranged in an array, and two adjacent lamp regions 50 in the plurality of lamp regions 50 are arranged equidistantly. It should be noted that the “equidistantly” here can be “about” equidistance or “approximate” equidistance, which is not limit herein. Each of the lamp regions 50 is configured to be electrically connected with a corresponding micro light emitting diode through the potential wire 31 and the bonding electrode 32 of a corresponding region. Because in embodiments of the present disclosure, the outermost edge of the pixel driving circuit 20 is further away from the same-side edge of the base substrate 10 than the outermost edge of the wiring layer 30, the space occupied by the pixel driving circuit 20 at the edge of the driving backplane is effectively reduced. Particularly when the edge space is reduced and the line width of the edge wire 311 is further reduced, even if the driving backplane is tiled with another driving backplane designed based on the concept of the present disclosure, it still can be ensured that the distance between two lamp regions 50 at outermost edges of the two driving backplanes and the distance between two adjacent lamp regions 50 in a single driving backplane is equal, to ensure display uniformity. The specific number of the plurality of lamp regions 50 may be set according to actual application requirements, which is not limited herein.

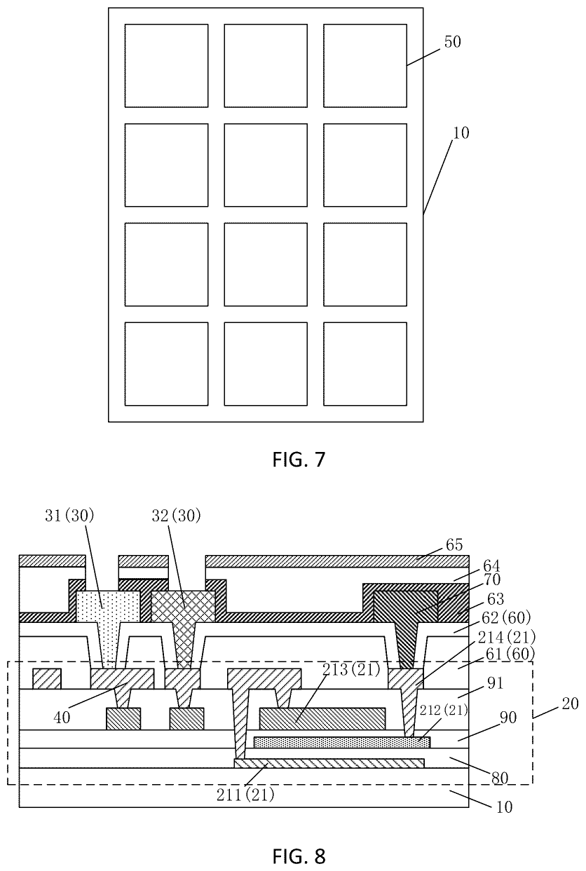

In embodiments of the present disclosure, as shown in FIG. 8, along a direction away from the base substrate 10, a conductive layer 21 of the pixel driving circuit 20 includes a first gate layer 211, an active layer 212, a second gate layer 213, and a first source-drain electrode layer 214 sequentially arranged. The driving backplane includes an insulating layer 60 and a second source-drain electrode layer sequentially arranged on a side of the first source-drain electrode layer 214 away from the base substrate 10. The transfer electrode 40 is in the first source-drain electrode layer 214. The potential wire 31 and the bonding electrode 32 are located in the second source-drain electrode layer 70.

In a specific implementation process, as shown in FIG. 8, the driving backplane further includes a buffer layer 80 between the first gate layer 211 and the active layer 212, a gate insulating layer 90 between the active layer 212 and the second gate layer 213, an interlayer insulating layer 91 between the second gate layer 213 and the first source-drain electrode layer 214, a planarization lay 61 and a first passivation layer 62 sequentially arranged away from the base substrate 10 and included in the insulating layer 60 between the first source-drain electrode layer 214 and the second source-drain electrode layer 70, and a second passivation layer 63, a second planarization layer and a third passivation layer 65 on the second source-drain electrode layer 70 and sequentially arranged away from the base substrate 10. Of course, for the driving backplane according to embodiments of the present disclosure, in addition to related film layers mentioned above, other film layer structures may also be provided according to actual application requirements, which is not limited herein.

Moreover, the transfer electrode 40 is located in the first source-drain electrode layer 214, and the potential wire 31 and the bonding electrode 32 are located in the second source-drain electrode layer 70. Accordingly, the first source-drain electrode layer 214 can be used to prepare a pattern of the transfer electrode 40 on the same layer and with the same material. The second source-drain electrode layer 70 can also be used to prepare a pattern of the potential wire 31 and a pattern of the bonding electrode 32 on the same layer and with the same material. Therefore, the manufacturing process is simplified, and the manufacturing cost is reduced.

In embodiments of the present disclosure, along an extending direction of the outermost edge of the wiring layer 30, the edge wire 311 is arranged discontinuously to form a plurality of discontinuous parts 310, and the discontinuous parts 310 are electrically connected through the transfer electrode 40 formed from the first source-drain electrode layer 214.

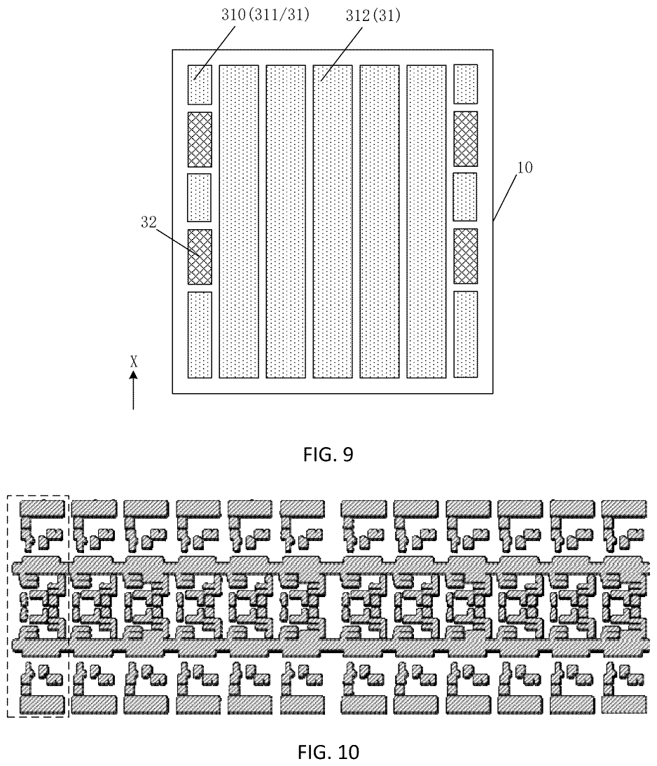

In a specific implementation process, as shown in FIG. 9, along the extension direction of the outermost edge of the wiring layer 30, such as the direction indicated by an arrow X in FIG. 9, the edge wire 311 is arranged discontinuously to form a plurality of discontinuous parts 310, and the respective discontinuous parts 310 are electrically connected through the transfer electrode 40 formed from the first source-drain electrode layer 214. In this way, the occupancy rate of the edge wire 311 to the edge space is reduced, and signal transmission performance of the driving backplane is ensured.

In an embodiment, an orthographic projection of the outermost edge of the pixel driving circuit 20 on the base substrate 10 is overlapped with an orthographic projection of an edge of the first source-drain electrode layer 214 on the same side as the outermost edge of the pixel driving circuit on the base substrate 10. That is, the outermost edge of the first source-drain electrode layer 214 is the outermost edge of the pixel driving circuit 20 on the same side as the outermost edge of the first source-drain electrode layer 214.

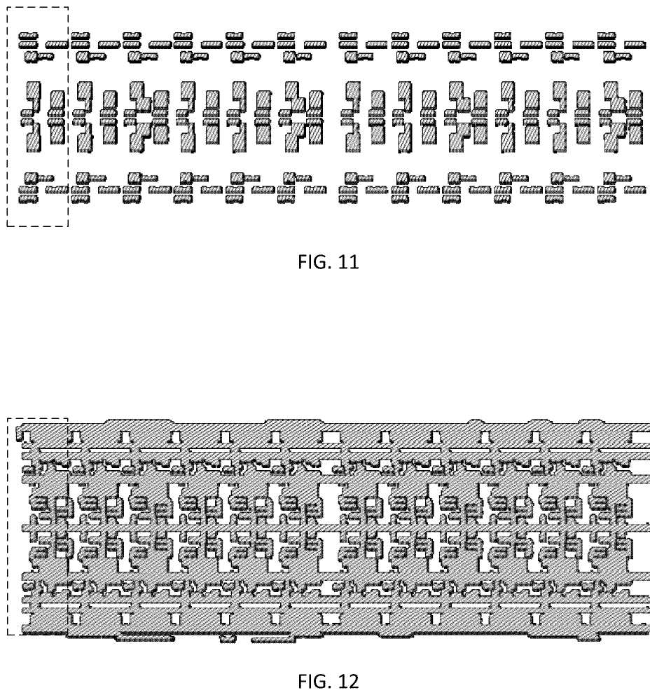

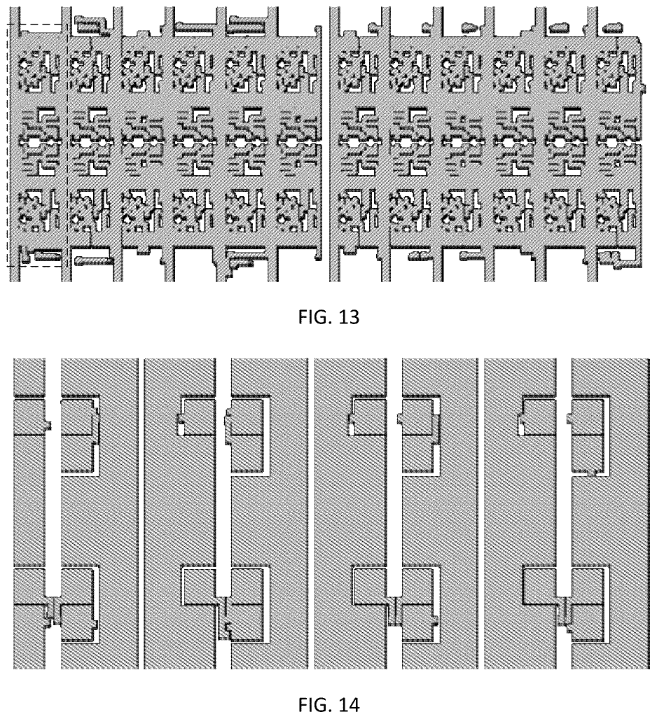

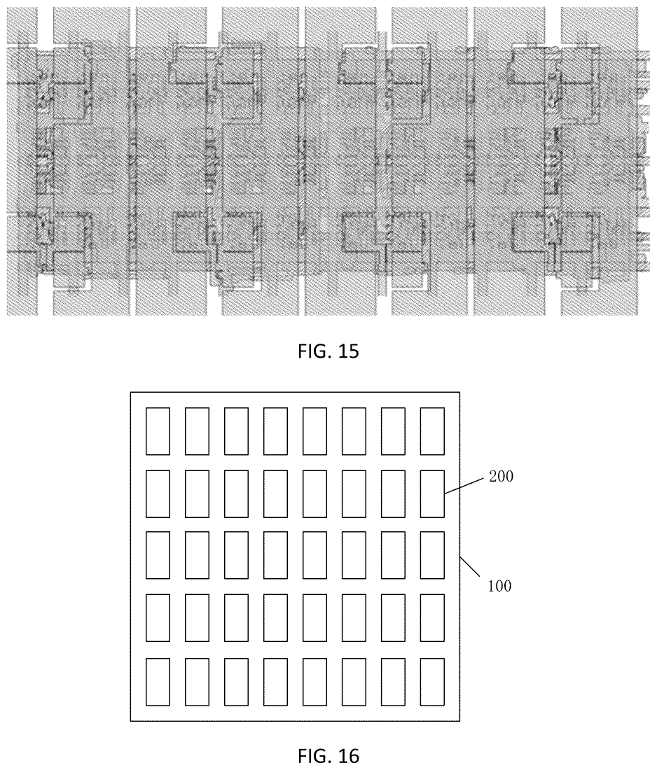

In order to clearly illustrate the inventive concept of the present disclosure, a corresponding explanation will be made in connection with a specific Layout. In an embodiment, as shown in FIGS. 11 to 15, FIG. 10 shows a pattern of a first gate layer 211 in a region Q in FIG. 2, FIG. 11 shows a pattern of an active layer 212 in a region Q in FIG. 2, FIG. 12 shows a pattern of a second gate layer 213 in a region Q in FIG. 2, FIG. 13 shows a pattern of a first source-drain electrode layer 214 in a region Q in FIG. 2, FIG. 14 shows a pattern of a second source-drain electrode layer 70 in a region Q in FIG. 2, and FIG. 15 shows a pattern after associated conductive layers 21 in a region Q in FIG. 2 are superimposed. It should be noted that in embodiments, a structure within a dashed box in each of FIGS. 10 to 13 actually corresponds to the smallest repeating unit of the pixel driving circuit 20, which is arranged correspondingly to two sub-pixels. Accordingly, the region Q is actually arranged correspondingly to 2*12 sub-pixels. If each pixel includes three sub-pixels including a red sub-pixel, a green sub-pixel and a blue sub-pixel, the region Q is actually arranged correspondingly to 2*4 pixels. In an actual manufacturing process, the pixel driving circuit 20 corresponding to 2*12 sub-pixels can be used as a basic inward shift unit, a center of the pixel driving circuit 20 corresponding to the 24 sub-pixels is used as a reference for the inward shift, and the center position is constant before and after the inward shift. Therefore, the space occupied by the driving backplane at the edge is reduced, the electrostatic protection capability is considered, and provides the possibility for subsequent tiling. The sectional structural diagram along the direction indicated by NN in FIG. 15 may be as shown in FIG. 8. The description of relevant structural film layers refers to the description of the relevant part above, and will not be repeated here.

In embodiments of the present disclosure, the distance between the outermost edge of the wiring layer 30 and the edge of the base substrate 10 on the same side as the outermost edge of the wiring layer 30 is in a range of 139 μm to 179 μm. The distance between the outermost edge of the pixel driving circuit 20 and the edge of the base substrate 10 on the same side as the outermost edge of the pixel driving circuit 20 is in a range of 180 μm to 220 μm. Illustratively, the distance between the outermost edge of the wiring layer 30 and the edge of the base substrate 10 on the same side as the outermost edge of the wiring layer 30 is 159 μm. The distance between the outermost edge of the pixel driving circuit 20 and the edge of the base substrate 10 on the same side as the outermost edge of the pixel driving circuit 20 is 200 μm. Of course, the specific value of the distance between the outermost edge of the wiring layer 30 and the edge of the base substrate 10 on the same side as the outermost edge of the wiring layer 30 may also be set according to actual application requirements. The specific distance value between the outermost edge of the pixel driving circuit 20 and the edge of the base substrate 10 on the same side as the outermost edge of the pixel driving circuit 20 may also be set according to actual application requirements, which is not limited herein.

Based on the same disclosed concept, as shown in FIG. 16, an embodiment of the present disclosure further provides a display panel. The display panel includes a driving backplane 100 as described in any of the above driving backplane 100, and a plurality of micro light emitting diodes 200 bonded on the driving backplane 100. The plurality of micro light emitting diodes 200 may be arranged according to actual application requirements, which is not limited herein. The principle of solving the problem of the display panel is similar to that of the aforementioned driving backplane 100. Therefore, implementations of the display panel can be referred to implementations of the driving backplane 100, and the repetition is omitted.

In a specific implementation process, the display panel according to embodiment of the present disclosure can be any product or component with display function, such as a mobile phone, a tablet computer, a television, a display, a notebook computer, a digital photo frame, a navigation device. Other essential components for the display panel are as will be understood by those skilled in the art, which will neither be described in detail herein, nor should it be taken as a limitation on the present disclosure.

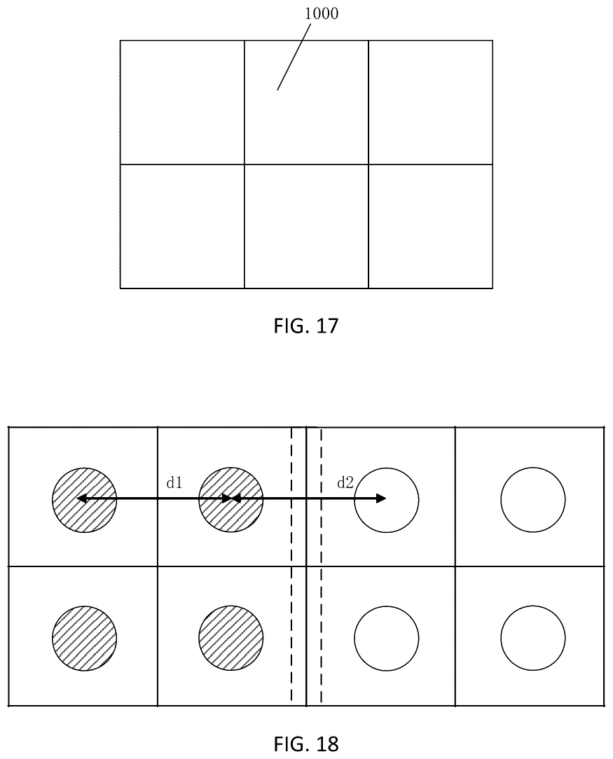

Based on the same disclosed concept, as shown in FIG. 17, an embodiment of the present disclosure further provides a tiled display device. The tiled display device includes a plurality of display panels 1000 as described above. The principle of solving the problem of the tiled display device is similar to that of the driving backplane 100. Therefore, implementations of the tiled display device can be referred to implementations of the driving backplane 100, and repetition is omitted.

It should be noted that the inventor found in the actual research that in order to realize the narrow bezel design of a single driving backplane, even for the seamless tiling between the driving backplanes, the design space at the edge of the driving backplane is often smaller than that in the plane. However, during the production process, there will be cutting lines, edge grinding lines, etc. at the edge of the driving backplane, and once there are any lines below them, it will cause the risk of membrane rupture, short circuit and reliability.

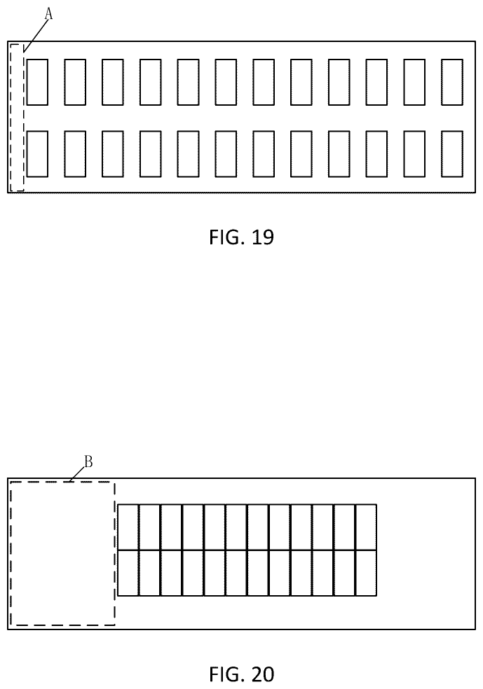

In an embodiment, two driving backplanes are taken as an example, as shown in FIG. 18, a circular structure represents a single micro light emitting diode. In order to ensure that a distance between two micro light emitting diodes at edges of two tiled driving backplanes is equal to a distance between two micro light emitting diodes in a single driving backplane (i.e. d1=d2), and space for cutting lines and edge grinding lines is reserved, the space left for the pixel driving circuit and the potential wire is relatively reduced. In embodiments of the present disclosure, a gap between pixel driving circuits corresponding to a plurality of sub-pixels can be combined, to leave more space at the edge of the driving backplane. In addition, in embodiments of the present disclosure, the outermost edge of the pixel driving circuit is farther away from the same-side edge of the base substrate than the edge of the wiring layer, this is equivalent to that the pixel driving circuit moves inward relative to a plane of a single drive backplane. As shown in FIG. 19 and FIG. 20, FIG. 19 is a simplified top view of a structure before inward movement. FIG. 20 is a simplified top view of a structure after inward movement. A dotted line box A and a dotted line box B represent the edge space. In an embodiment, taking the pixel driving circuit corresponding to 2*12 sub-pixels as a basic unit as an example, the edge space before inward movement is less, the circuit is easy to be damaged in the production process, and the production yield is reduced. The edge space after inward movement is effectively improved compared with the edge space before inward movement. In embodiments of the present disclosure, although the edge space is still relatively small, and the line width of the edge wire is small relative to the line width of the middle wire, the inward movement of the pixel driving circuit brings the outermost edge of the wiring layer closer to the same-side edge of the base substrate, the wiring layer can shield the pixel driving circuit to a certain extent, so that the ESD can be effectively conducted away through the wiring layer, to improve the production yield.

Although embodiments of the present disclosure have been described, those skilled in the art may otherwise make various modifications and variations to these embodiments once they are aware of the basic inventive concept. Therefore, the claims intend to include embodiments as well as all these modifications and variations falling within the scope of the present disclosure.

Apparently, those skilled in the art can make various modifications and variations to embodiments of the present disclosure without departing from the spirit and scope of embodiments of the present disclosure. In this way, if the modifications and variations of embodiments of the present disclosure fall within the scope of the claims of the present disclosure and their equivalent technologies, the present disclosure is also intended to include these modifications and variations.

1. A driving backplane, comprising:
a base substrate;
a pixel driving circuit on the base substrate; and
a wiring layer on a side of the pixel driving circuit away from the base substrate, wherein the wiring layer comprises a pattern of a potential wire and a pattern of a bonding electrode, and the bonding electrode is used for bonding a micro light emitting diode;
wherein a distance between an outermost edge of the wiring layer and an edge of the base substrate on the same side as the outermost edge of the wiring layer is smaller than a distance between an outermost edge of the pixel driving circuit and an edge of the base substrate on the same side as the outermost edge of the pixel driving circuit.

2. The driving backplane according to claim 1, further comprising a transfer electrode located between the potential wire and the base substrate, and electrically connected with the potential wire and the pixel driving circuit respectively, wherein an orthographic projection of the potential wire on the base substrate and an orthographic projection of the transfer electrode on the base substrate are in a mesh structure, and the mesh structure is configured as an electrostatic protection unit.

3. The driving backplane according to claim 2, wherein the potential wire comprises an edge wire at an outermost side and a middle wire in a middle region, wherein a line width of the edge wire is smaller than a line width of the middle wire.

4. The driving backplane according to claim 3, wherein the bonding electrode at the outermost edge of the wiring layer is flush with the edge wire on the same side as the bonding electrode.

5. The driving backplane according to claim 1, wherein the base substrate is divided into a plurality of lamp regions arranged in an array; wherein adjacent two lamp regions in the plurality of lamp regions are arranged equidistantly, and each of the lamp regions is configured to be electrically connected with a corresponding micro light emitting diode through the potential wire and the bonding electrode of a corresponding region.

6. The driving backplane according to claim 5, wherein along a direction away from the base substrate, a conductive layer of the pixel driving circuit comprises a first gate layer, an active layer, a second gate layer and a first source-drain electrode layer sequentially arranged; the driving backplane comprises an insulating layer and a second source-drain electrode layer sequentially arranged on a side of the first source-drain electrode layer away from the base substrate; the transfer electrode is in the first source-drain electrode layer, and the potential wire and the bonding electrode are in the second source-drain electrode layer.

7. The driving backplane according to claim 6, wherein along an extending direction of the outermost edge of the wiring layer, an edge wire is arranged discontinuously to form a plurality of discontinuous parts, and the discontinuous parts are electrically connected through a transfer electrode formed from the first source-drain electrode layer.

8. The driving backplane according to claim 7, wherein an orthographic projection of the outermost edge of the pixel driving circuit on the base substrate is overlapped with an orthographic projection of an edge of the first source-drain electrode layer on the same side as the outermost edge of the pixel driving circuit on the base substrate.

9. The driving backplane according to claim 1, wherein the distance between the outermost edge of the wiring layer and the edge of the base substrate on the same side as the outermost edge of the wiring layer is in a range of 139 μm to 179 μm, and the distance between the outermost edge of the pixel driving circuit and the edge of the base substrate on the same side as the outermost edge of the pixel driving circuit is in a range of 180 μm to 220 μm.

10. A display panel, comprising:
the driving backplane according to claim 1, and a plurality of micro light emitting diodes bonded on the driving backplane.

11. A tiled display device, comprising:
a plurality of display panels each according to claim 10.
